(19) United States
(12) Patent Application Publication
(10) Pub. No.: US 2026/0255520 A1
(43) Pub. Date: Aug. 27, 2026

(54) EXTERNAL LOCKING MECHANISM FOR A NETWORK INTERFACE CARD

(71) Applicant: DELL PRODUCTS L.P., Round Rock, TX (US)

(72) Inventors: Jonathan F. Lewis, Round Rock, TX (US); Corey D. Hartman, Hutto, TX (US)

(21) Appl. No.: 19/064,935

(22) Filed: Feb. 27, 2025

(51) Int. Cl. H05K 7/14; G06F 1/18

(52) U.S. Cl. CPC H05K 7/1418; G06F 1/185; H05K 7/1487

(57) ABSTRACT

A card retention mechanism of an information handling system includes a guide rail and a latch. The guide rail includes a channel formed by a top section, a bottom section and a side section. The latch is rotatably attached to the side section. When the latch is in an unlocked position, a card is able to slide an entire length of the channel. When the latch is in a locked position, the card is retained within the channel.

### FIELD OF THE DISCLOSURE

The present disclosure generally relates to information handling systems, and more particularly relates to an information handling system having an external locking mechanism for a network interface card.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A card retention mechanism of an information handling system includes a guide rail and a latch. The guide rail includes a channel formed by a top section, a bottom section and a side section. The latch is rotatably attached to the side section. When the latch is in an unlocked position, a card is able to slide an entire length of the channel. When the latch is in a locked position, the card is retained within the channel.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of an information handling system according to at least one embodiment of the present disclosure;

FIG. 2 is a diagram of a portion of a card assembly with an external locking mechanism according to at least one embodiment of the present disclosure;

FIG. 3 is a diagram of a portion of an information handling system with a network interface card inserted within a connector and a rail lock in an unlocked position according to at least one embodiment of the present disclosure;

FIG. 4 is a diagram of a cross section of a portion of an information handling system with a network interface card inserted within a connector and a rail lock in an unlocked position according to at least one embodiment of the present disclosure;

FIG. 5 is a diagram of a portion of an information handling system with a network interface card inserted within a connector and a rail lock in a locked position according to at least one embodiment of the present disclosure;

FIG. 6 is a diagram of a cross section of a portion of an information handling system with a network interface card inserted within a connector and a rail lock in a locked position according to at least one embodiment of the present disclosure; and

FIG. 7 is a diagram of a portion of an information handling system with a network interface card inserted within a connector with an indicator light pipe according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

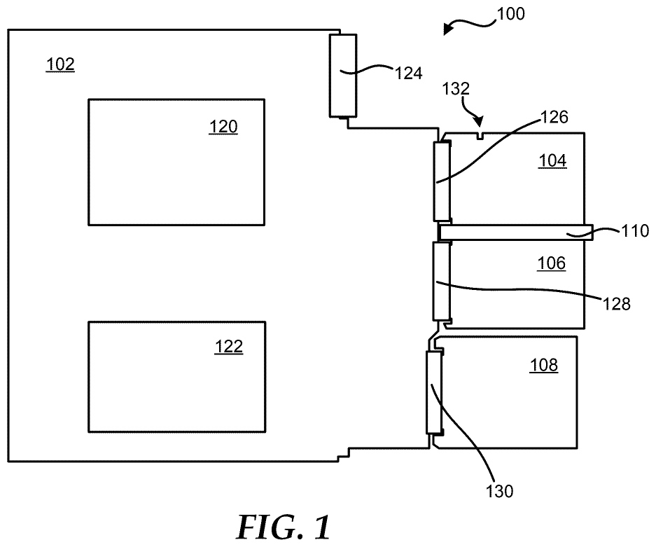

FIG. 1 illustrates a portion of an information handling system 100 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a motherboard 102, multiple network interface cards 104, 106, and 108, and a guide rail 110. Motherboard 102 includes processors 120 and 122 and connectors 124, 126, 128, and 130. In certain examples, network interface cards 104, 106, and 108 may each include one or more notches, such as notch 132 in card 104. Information handling system 100 may be a hot-plug enabled system, such as a storage system, and may extend hot-plug capabilities to storage systems that leverage server platforms/chassis. Information handling system 100 may include additional components without varying from the scope of the disclosure.

In certain examples, different cards may plug into connectors 124, 126, 128, and 130 to provide electrical communication between the corresponding card and one or both of processors 120 and 122. For example, processors 120 and 122 may communicate with network interface card 104 via connector 126, with card 106 via connector 128, and with card 108 via connector 130. In an example, as interface card 104 is inserted within a bay of information handling system 100, guide rail 110 may provide proper alignment between card 104 and connector 126. Similarly, as interface card 106 is inserted within a bay of information handling system 100, guide rail 110 may provide proper alignment between card 106 and connector 128.

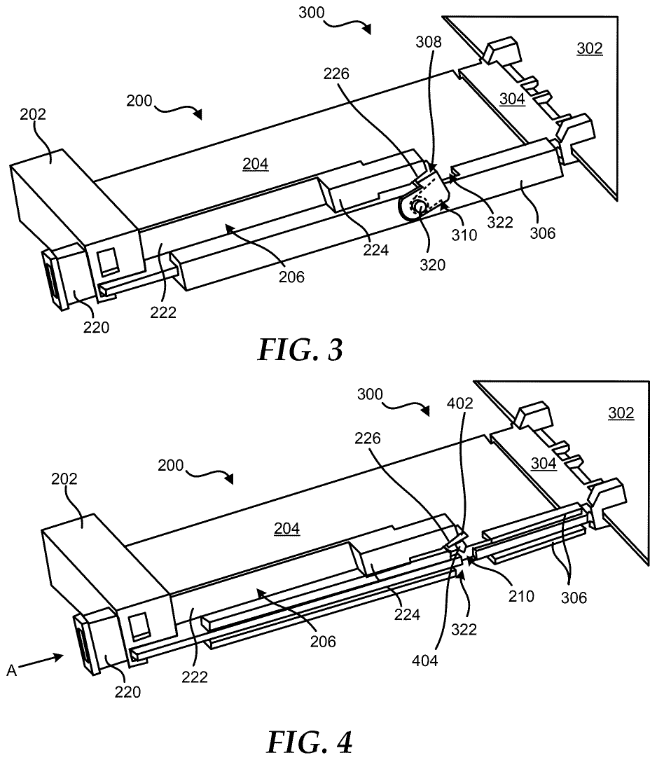

While only a single guide rail 110 is illustrated in FIG. 1, information handling system 100 may include any suitable number of guide rails to provide proper alignment and retention of interface cards 104, 106, and 108 within respective bays of the information handling system. For example, another guide rail, such as guide rail 306 in FIG. 3, may be located on the opposite edge of connector 126. In an example, this other guide rail may provide additional alignment features between card 104 and connector 126. Additionally, this guide rail, such as guide rail 306 in FIG. 3, may include one or more components to physically interface with notch 132 of card 104 and enable retention of the card within connector 126 and motherboard 102 as will be described with respect to FIGS. 3-6 below.

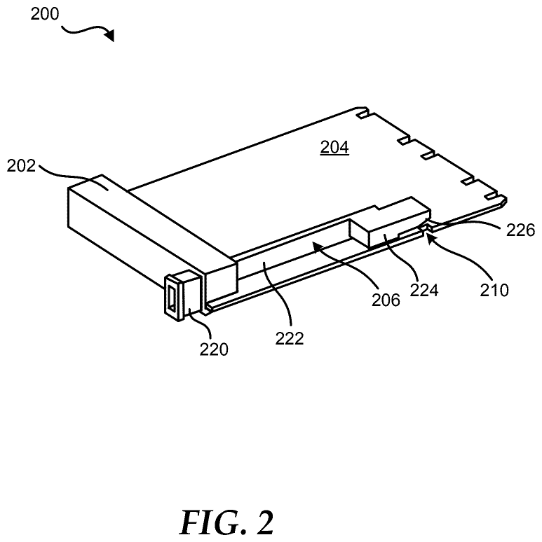

FIG. 2 illustrates a portion of a card assembly 200 according to at least one embodiment of the present disclosure. Card assembly 200 includes a faceplate 202, a network interface card 204 and a push rod 206. Network interface card 204 may be substantially similar to cards 104, 106, and 108 of FIG. 1. Card 204 includes a notch 210. Push rod 206 includes a handle 220, a rod portion 222, a latch interface portion 224, and a ramp portion 226. Card assembly 200 may include additional components without varying from the scope of the disclosure.

In an example, the dimensions of card assembly 200 may correspond to any suitable specification design form factor. For example, card assembly 200 may correspond with the form factor of the open compute project (OCP) network interface card (NIC) 3.0 specification. In certain examples, card assemblies designed according to the OCP NIC 3.0 specification have one of three different front panels, such as an internal lock, cam latch, and pull-tab/thumbscrew. In an example, card assembly 200 may be configured for an OCP NIC 3.0 v1.4 Dual Small Form Factor (DSFF) board that is compatible with OCP data center modular hardware system (DC-MHS) high bandwidth memory (HBM) specifications. In certain examples, faceplate 202 may be an internal lock version faceplate for use with card 204. Faceplate 202 of card assembly 200 may enable external service for card 204 in a mechanical form factor and system intended only for cold/internal service. In an example, card assembly 200 may enable card 204 to include hot plug/surprise removal circuitry.

As illustrated in FIG. 2, handle 220 extends in front of faceplate 202 when push rod 206 is in an unlocked position. In an example, rod portion 222 may extend from handle 220, through faceplate 202, and connect with latch interface portion 224. When push rod 206 is in the unlocked position, ramp portion 226 may be located above notch 210 of card 204. In an example, handle 220 of push rod 206 may hold in a locked position when depressed, or snap to an unlocked position when released or pushed again.

In certain examples, push rod 206 is located on one side or edge of faceplate 202, and the other side or edge of the faceplate may include a pull-tab for removal assistance of card assembly 200. The use on the pull-tab may enable serviceability of card 204 without removing the cover of an information handling system. In an example, faceplate 202 may incorporate push rod 206 and remain the same width as defined by a specification. The specification may be any suitable specification, such as the OCP NIC 3.0 specification and faceplate 202 may be the same width as the internal lock faceplate design of this specification. In an example, handle 220 may include a pull tab. In this example, handle 220 may support a removal force, such that a user may grip the pull tab and pull on the handle to remove card assembly 200 from an information handling system, such as information handling system 100 of FIG. 1.

FIGS. 3-7 illustrate a portion of an information handling system 300 according to at least one embodiment of the present disclosure. Information handling system 300 may be substantially similar to information handling system 100 of FIG. 1. Information handling system 300 includes a motherboard 302, a connector 304, a guide rail 306, a rail latch 308, a spring 310, and card assembly 200. Spring 310 may be any suitable type of spring, such as a torsion spring. Guide rail 306 includes a post 320 that extends through and enables rotation of rail latch 308. Guide rail 306 also includes a gap or opening 322 to enable rail latch 308 to interface with card 204. In an example, guide rail 306, rail latch 308, and spring 310 may combine to form a card retention mechanism within information handling system 300. Card assembly 200 includes faceplate 202, network interface card 204 and push rod 206. Push rod 206 includes handle 220, rod portion 222, latch interface portion 224, and ramp portion 226. Information handling system 300 may include additional components without varying from the scope of this disclosure.

In an example, guide rail 306 may be attached to motherboard 302, to a server chassis, or the like. While only guide rail 306 is illustrated in FIGS. 3-7, information handling system 300 may include another guide rail, such as guide rail 110 of FIG. 1, on the other side or edge of card 204. In an example, guide rail 306 may enable proper alignment of card 204 with connector 304 as card assembly 200 is inserted within information handling system 300. Rail latch 308 includes an interface portion 402 and a pin 404 as illustrated in the cross-section views shown in FIGS. 4 and 6.

Referring to FIGS. 3 and 4, spring 310 may bias rail latch 308 toward the unlocked position. When rail latch 308 is in the unlocked position, pin 404 may be located above a channel 406, illustrated in FIG. 4, in guide rail 306. In an example, channel 406 may be formed by a top section, a bottom section, and a side section of guide rail 306. Based on pin 404 being above channel 406, card 204 may slide along channel 406 without interference from the pin as card assembly 204 is inserted into information handling system 300. In an example, push rod 206 may be in an unlocked position when card assembly 200 is either inserted into or removed from information handling system 300. When push rod 206 is in the unlocked position, handle 220 is in an extended position with respect to faceplate 202, and latch interface portion 224 may be nearer to the faceplate as compared to when the push rod is in the locked position. This location of latch interface portion 224 may enable card assembly 200 to be inserted and removed from information handling system 300 when push rod is in the unlocked position.

When card assembly 200 is fully inserted within information handling system 300 and card 204 is fully inserted within connector 304, ramp portion 226 of push rod 206 may be in physical contact with rail latch 308 or may be located substantially close to interface portion 402 of the rail latch. In this example, card assembly 200 may be fully inserted within information handling system 300 without automatically forcing rail latch 308 toward the locked position.

In an example, a user may exert a force on push rod 206 in the direction of arrow A, which in turn may cause the push rod to transition from the unlocked to the locked position. During the movement or transition of push rod 206 from the unlocked to the locked position, ramp portion 226 may exert a force on interface portion 402 of rail latch 308. This force may be greater than the force of spring 310, such that rail latch 308 may rotate around post 320 and compress spring 310. In an example, post 320 may extend from the side section of guide rail 306.

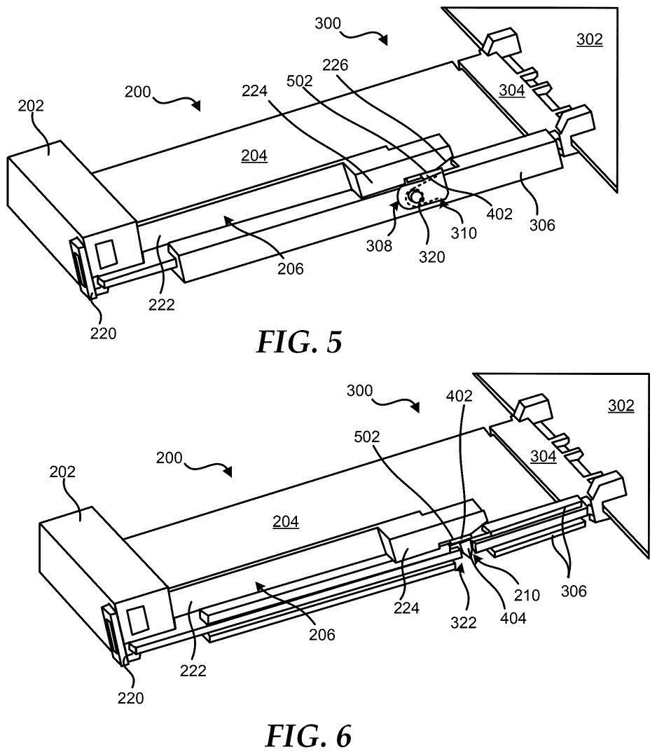

Referring to FIGS. 5 and 6, when push rod 206 is in the locked position, interface portion 402 of rail latch 308 is in physical contact with a lock section 502 of latch interface portion 224. In an example, lock section 502 may hold rail latch in the locked position, such that pin 404 is inserted through notch 210 of card 204. Based on pin 404 being inserted through notch 210, card 204 and card assembly 200 may be securely held within information handling system 300. Thus, an individual may not be able to remove card assembly and card 204 from information handling system 300 while push rod 206 and rail latch 308 are both in the locked position.

In an example, when push rod 206 is in the locked position, handle 220 may be in a retracted position as shown in FIGS. 5 and 6. While handle 220 is illustrated as being located slightly out from the front panel of faceplate 202, the handle 220 may be substantially flush with the front panel without varying from the scope of this disclosure. Push rod 206 and rail latch 308 may both remain in locked positions until another force is exerted on handle 220.

In response to the force on handle 220, the handle may extend from faceplate 202 and pull rod portion 222, latch interface portion 224, and ramp portion 226 toward the faceplate and away from rail latch 308. Based on the movement of these components of push rod 206, lock section 502 may no longer be in physical contact with rail latch 308, such that spring 310 may push rail latch toward the unlocked position. When rail latch 308 is in the unlocked position, card assembly 200 and card 204 may be removed from information handling system 300.

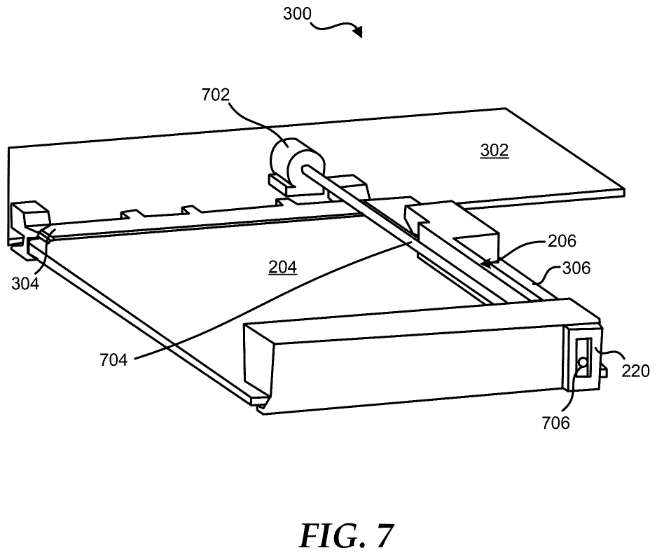

Referring to FIG. 7, information handling system 300 may also include an indicator light source 702, a light pipe 704, and an indicator port 706. In an example, indicator light source 702 may be any suitable light source, such as a light emitting diode (LED) or the like. When card 204 is fully inserted within connector 304, light pipe 704 may extend between indicator light source 702 and indicator port 706. In an example, light pipe 704 may transmit any light from indicator light source 702 to indicator port 706 so that an individual may view the indicator light.

In certain examples, light pipe 704 may be permanently affixed to indicator port 706 in handle 220. Light pipe 704 may extend along side push rod 206 and guide rail 306 may provide proper alignment of light pipe 704 with indicator light source 702. Based on this alignment, light pipe 704 may be inserted into indicator light source 702 as card 204 is inserted into connector 304. In certain examples, light pipe 704 may be inserted further into indicator light source 702 when push rod 206 is in the locked position as compared to when the push rod is in the unlocked position.

In an example, indicator light source 702 may communicate with a processor of motherboard 302, such that the processor may control the light provided along light pipe 704 to indicator port 706. In this example, the processor may utilize light provided by indicator light source 702 to transmit different indications to an individual associated with information handling system 300. In certain examples, the indication may include, but is not limited to, whether removal of card 204 is safe and a cold or hot removal condition. In an example, indicator light source 702 may provide any suitable state information including, but not limited to, ready to remove, not ready to remove, card is hot (active), and card is cold (inactive). The indications provided from indicator light source 702 to indicator port 706 via light pipe 704 may allow service personnel to determine when card 204 may be safely removed from information handling system 300.

As described herein, push rod 206 and rail latch 308 may enable locking/unlocking of card 204 and card assembly 200 in information handling system 300. The bay to receive card assembly 200 and card 204 may be a small form factor (SFF), tall small form factor (TSFF), DSFF, or the like. In an example, push rod 206 provide a mechanism to operate an internal latch form factor from outside the information handling system chassis, which may allow easier serviceability of card 204.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A card retention mechanism of an information handling system, the card retention mechanism comprising:
a guide rail including a channel formed by a top section, a bottom section and a side section; and
a latch rotatably attached to the side section, when the latch is in an unlocked position a card is able to slide an entire length of the channel, and when the latch is in a locked position, the card is retained within the channel.

2. The card retention mechanism of claim 1, wherein the latch is a spring loaded latch.

3. The card retention mechanism of claim 2, further comprising: a spring in physical contact with both the latch and the bottom section.

4. The card retention mechanism of claim 3, wherein the spring biases the latch toward the unlocked position.

5. The card retention mechanism of claim 1, wherein the latch includes a pin, wherein the pin is located with the channel when the latch is in the locked position, and the pin is located outside the channel when the latch is in the unlocked position.

6. The card retention mechanism of claim 5, wherein the guide rail includes a gap to enable the pin to enter the channel when the latch is in the locked position.

7. The card retention mechanism of claim 1, further comprising: a post extended from the side section, wherein the latch rotates around the post to transition between the unlocked position and the locked position.

8. An information handling system comprising:
a card assembly including a card and a push rod; and
a card retention mechanism in physical contact with the card, the card retention mechanism includes:
a guide rail including a channel formed by a top section, a bottom section and a side section, wherein the channel receives the card; and
a latch rotatably attached to the side section and in physical contact with the push rod when the card assembly is within the information handling system, when the latch is in an unlocked position the card is able to slide an entire length of the channel, and when the latch is in a locked position, the card is retained within the channel.

9. The information handling system of claim 8, wherein the card assembly further includes a faceplate in physcial contact with the push rod.

10. The information handling system of claim 8, wherein the push rod includes a handle, wherein the push rod transisitions between a second unlocked position and a second locked position based on a force exerted on the handle.

11. The information handling system of claim 8, wherein the handle includes a pull tab to enable a force to be exerted on the card assembly.

12. The information handling system of claim 8, further comprising: a spring in physical contact with both the latch and the bottom section.

13. The information handling system of claim 12, wherein the spring biases the latch toward the unlocked position.

14. The information handling system of claim 8, wherein the latch includes a pin, wherein the pin is located with the channel when the latch is in the locked position, and the pin is located outside the channel when the latch is in the unlocked position.

15. The information handling system of claim 14, wherein the guide rail includes a gap to enable the pin to enter the channel when the latch is in the locked position.

16. The information handling system of claim 8, wherein the card retention mechanism further includes: a post extended from the side section, wherein the latch rotates around the post to transition between the unlocked position and the locked position.

17. An information handling system comprising:
a card assembly including:
a card;
a faceplate in physical contact with the card; and
a push rod extending through the faceplate, the push rod includes a lock section; and
a card retention mechanism in physical contact with the card, the card retention mechanism includes:
a guide rail including a channel formed by a top section, a bottom section and a side section, wherein the channel receives the card; and
a latch rotatably attached to the side section and in physical contact with the push rod when the card assembly is within the information handling system, when the latch is in an unlocked position the card is able to slide an entire length of the channel, and when the latch is in a locked position, the lock section of the push rod is in physical contact with the latch and the card is retained within the channel.

18. The information handling system of claim 17, wherein the push rod includes a handle, wherein the push rod transisitions between a second unlocked position and a second locked position based on a force exerted on the handle.

19. The information handling system of claim 17, further comprising: a spring in physical contact with both the latch and the bottom section.

20. The information handling system of claim 19, wherein the latch includes a pin, wherein the pin is located with the channel and a notch of the card when the latch is in the locked position, and the pin is located outside the channel and the notch of the card when the latch is in the unlocked position.
